(19) United States
(12) Patent Application Publication
(10) Pub. No.: US 2025/0324669 A1
(43) Pub. Date: Oct. 16, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Kuei-Yu KAO, Hsinchu (TW); Dong-Sheng SU, Yunlin (TW); Shih-Yao LIN, New Taipei (TW); Chun-Yu LIN, Yilan (TW); Yung-Chi CHANG, Hsinchu (TW); Ming-Ching CHANG, Hsinchu (TW)

(21) Appl. No.: 18/632,678

(22) Filed: Apr. 11, 2024

(51) Int. Cl. H01L 29/423; H01L 21/3065; H01L 21/8234; H01L 21/8238; H01L 27/088; H01L 29/06; H01L 29/08; H01L 29/66; H01L 29/775; H01L 29/786

(52) U.S. Cl. CPC H10D 30/6735; H01L 21/3065; H10D 30/014; H10D 30/43; H10D 30/6757; H10D 62/115; H10D 62/121; H10D 62/151; H10D 64/017; H10D 64/018; H10D 84/0135; H10D 84/017; H10D 84/038; H10D 84/83

(57) ABSTRACT

Embodiments of the present disclosure provide semiconductor device structures and methods of forming the same. The structure includes first and second source/drain regions disposed over a substrate and an isolation region disposed between the first and second source/drain regions. The isolation region includes a first top surface having a slanted portion and a flat portion, and a portion of the isolation region located between the slanted portion of the first top surface and a plane defined by the flat portion of the first top surface has a width and a height. The width is greater than the height. The structure further includes a plurality of semiconductor layers disposed adjacent the first and second source/drain regions, a gate electrode layer surrounding a portion of each of the plurality of semiconductor layers, and a spacer disposed between the gate electrode layer and the first source/drain region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIG. 7 is a cross-sectional side view of the semiconductor device structure taken along line A-A of FIG. 6, in accordance with some embodiments.

FIGS. 8-12 are perspective views of various stages of manufacturing the semiconductor device structure, in accordance with some embodiments.

FIG. 13 is a cross-sectional top view of the semiconductor device structure taken along line B-B of FIG. 12, in accordance with some embodiments.

FIGS. 14-16 are perspective views of various stages of manufacturing the semiconductor device structure, in accordance with some embodiments.

FIG. 17 is a cross-sectional top view of the semiconductor device structure taken along line C-C of FIG. 16, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide a semiconductor device structure including an isolation region having a slanted top surface. As a result, the sacrificial gate electrode layer is free of residue, which leads to reduced gate electrode layer defects.

While the embodiments of this disclosure are discussed with respect to nanostructure channel FETs, such as Horizontal Gate All Around (HGAA) FETs, Vertical Gate All Around (VGAA) FETs, Forksheet FETs, implementations of some aspects of the present disclosure may be used in other processes and/or in other devices, such as FinFETs, planar FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

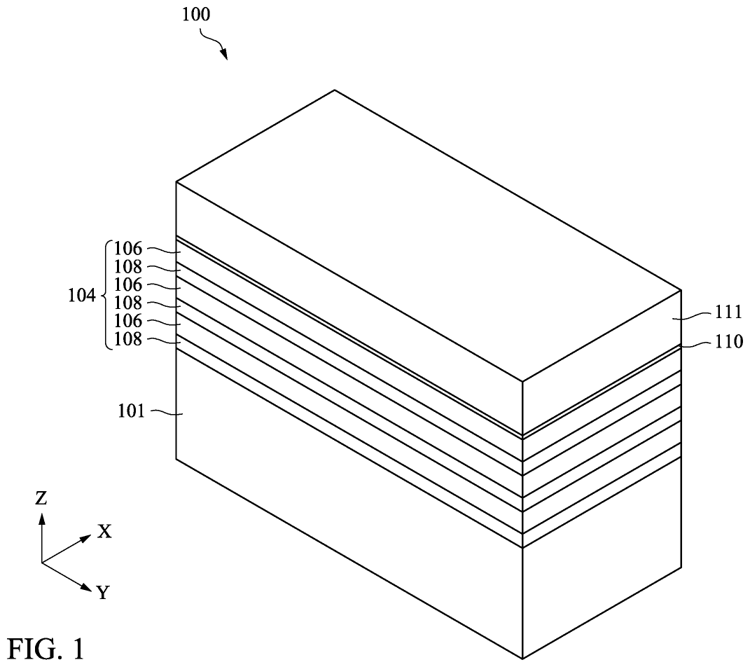

FIGS. 1-17 show exemplary processes for manufacturing a semiconductor device structure 100 according to embodiments of the present disclosure. It is understood that additional operations can be provided before, during, and after processes shown by FIGS. 1-17, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm, such as about 15 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

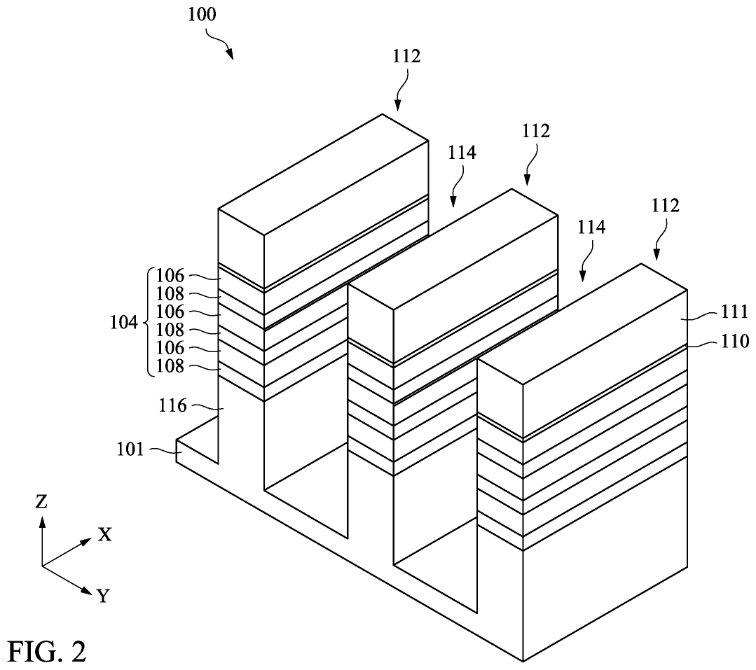

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

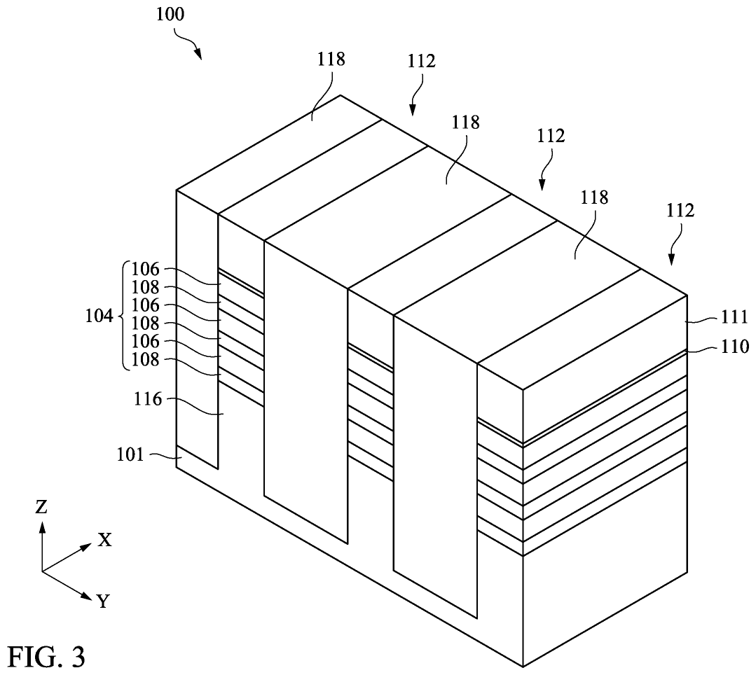

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

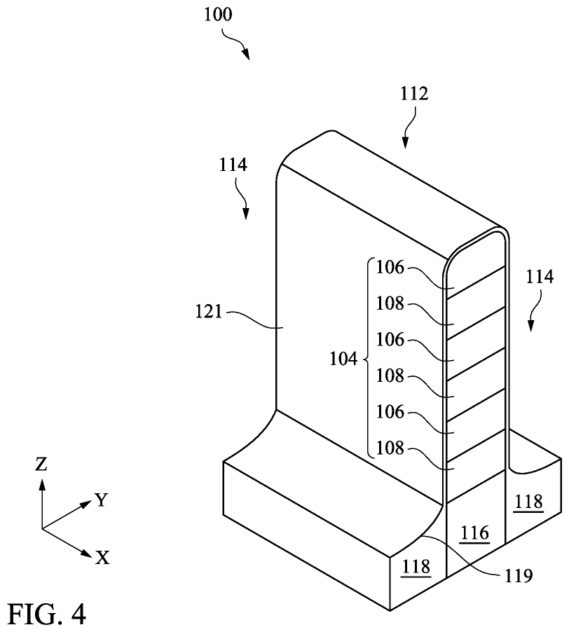

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. In some embodiments, a dry etching process is performed to recess the insulating material 118. For example, the dry etching process utilizes etchants such as NH₃, NF₃, HBr, H₂, or combinations thereof. In some embodiments, the dry etching process also utilizes passivation gas to enhance selectivity, and the passivation gas includes N₂, O₂, or a combination thereof. With the addition of the passivation gas during the dry etching process, the dry etching process etches the dielectric material of the insulating material 118, while the semiconductor materials of the first and second semiconductor layers 106, 108 are not substantially affected. The gas flow rate of the etchants and passivation gas ranges from about 20 standard cubic centimeters (sccm) to about 3000 sccm. The plasma power of the dry etching process may range from about 10 W to about 4000 W, and the processing pressure may range from about 10 mTorr to about 3 Torr.

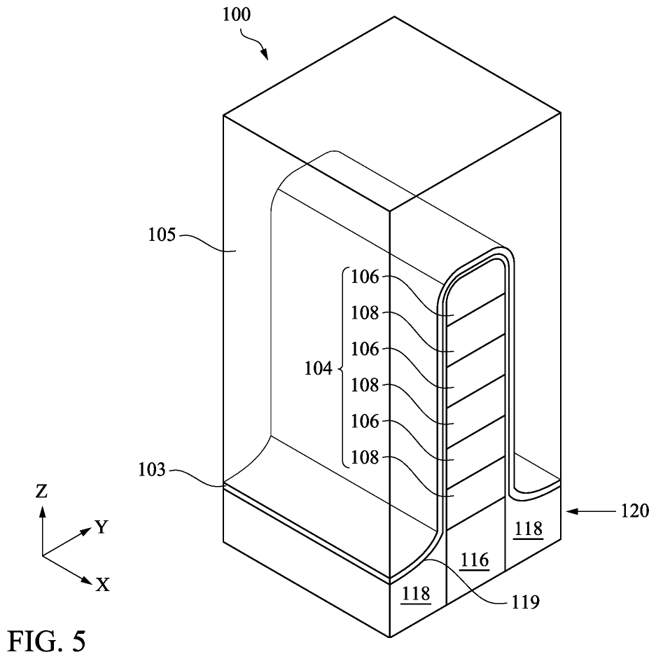

In some embodiments, a bias voltage is applied during the dry etching process to pull the ions towards the substrate 101. As a result, the top surface of the insulating material 118 is substantially flat. In some embodiments, the bias voltage is not applied during the dry etching process, and the top surface 119 of the insulating material 118 is slanted, as shown in FIG. 4. The slanted top surface 119 can lead to subsequently formed sacrificial gate electrode layer 134 (FIG. 5) free of residue, which can lead to reduced gate electrode layer defects. In some embodiments, a native oxide layer 121 is formed on the stack of semiconductor layers 104. The native oxide layer 121 may be the result of oxidation of the stack of semiconductor layers 104 when the semiconductor device structure 100 is exposed to the atmosphere, such as during transferring of the substrate from one processing chamber to another processing chamber. In some embodiments, the substrate is transferred from one processing chamber to another processing chamber within a cluster tool, and no native oxide layer is formed. In some embodiments, the isolation regions 120 are the STI. In some embodiments, the oxide layer 110 and the nitride layer 111 are also removed during the recessing of the insulating material 118.

In FIG. 5, a first sacrificial layer 103 is formed on the exposed surfaces of the semiconductor device structure 100, and a second sacrificial layer 105 is formed on the first sacrificial layer 103. In some embodiments, the first sacrificial layer 103 includes a dielectric material, such as an oxide, for example silicon oxide. The first sacrificial layer 103 may be formed by any suitable process, such as CVD or PECVD. In some embodiments, the first sacrificial layer 103 is a conformal layer formed by a conformal process, such as atomic layer deposition (ALD). In some embodiments, the second sacrificial layer 105 includes a semiconductor material, such as polysilicon. The second sacrificial layer 105 may be formed by any suitable process, such as CVD, PECVD, ALD, or PVD. The second sacrificial layer 105 may be first deposited to embed the fin structures 112, followed by a planarization process, such as a CMP process, as shown in FIG. 5. In some embodiments, the second sacrificial layer 105 may have a thickness in the Z direction ranging from about 100 nm to about 200 nm.

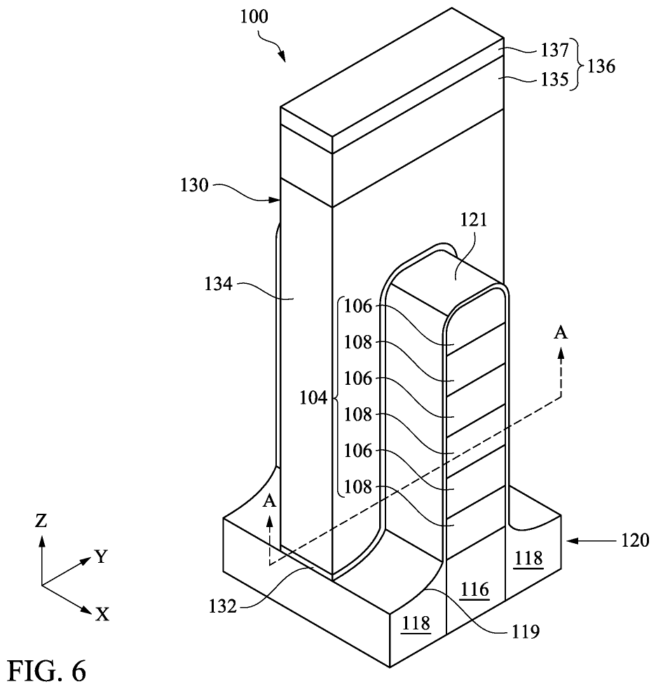

In FIG. 6, a mask structure 136 is formed on the second sacrificial layer 105, and the mask structure 136 is used to pattern the second sacrificial layer 105 to form one or more sacrificial gate electrode layers 134. In some embodiments, the mask structure 136 includes an oxide layer 135 and a nitride layer 137 formed on the oxide layer 135. The patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the patterning further includes an etching process that may include dry etching (e.g., RIE etching), wet etching, other etching methods, and/or combinations thereof. In some embodiments, the etching process is an anisotropic dry etching process using a chlorine-based etchant. In some embodiments, other etchants, such as HBr and/or oxygen-containing etchant, may be used. Carrier or dilute gas, such as Ar, N₂, or He, may be also used in addition to the etchants in the anisotropic dry etching process. The first sacrificial layer 103 is also patterned to form the sacrificial gate dielectric layer 132, as shown in FIG. 6. The sacrificial gate dielectric layer 132 and the sacrificial gate electrode layer 134 may form a sacrificial gate structure 130.

In some embodiments, the top surface of the isolation region 120 is substantially flat. As a result, residue from the second sacrificial layer 105 may be formed in the corners, such as on top of the topmost first semiconductor layer 106 and adjacent the bottom second semiconductor layer 108. In other words, the side surfaces of the sacrificial gate electrode layer 134 includes protrusions. After the gate replacement process, the gate electrode layers would also include these protrusions. As a result, electrical short between a gate electrode layer and a source/drain region may occur. In order to prevent the formation of the protrusions, the slanted top surface 119 of the isolation region 120 is formed. It has been observed that when the top surface 119 of the isolation region 120 is slanted, as shown in FIG. 6, the sacrificial gate electrode layer 134 is free of protrusions. In other words, the side surfaces of the sacrificial gate electrode layer 134 are substantially flat.

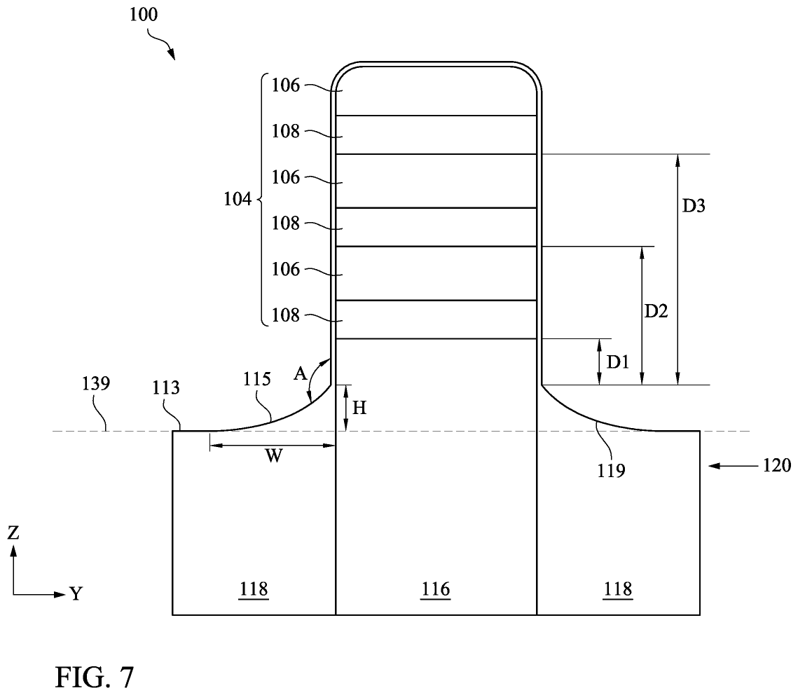

FIG. 7 is a cross-sectional side view of the semiconductor device structure 100 taken along line A-A of FIG. 6, in accordance with some embodiments. As shown in FIG. 7, the top surface 119 of the isolation region 120 includes a substantially flat portion 113 and a slanted portion 115. The slanted portion 115 extends from the substrate portion 116. The slanted portion 115 forms an angle A with respect to the side surface of the substrate portion 116. In some embodiments, the angle A is an obtuse angle ranging from about 105 degrees to about 130 degrees. The portion of the isolation region 120 from a plane 139 defined by the flat portion 113 of the top surface 119 to the slanted portion 115 has a height H in the Z direction and a width W in the Y direction. In some embodiments, the height H ranges from about 10 nm to about 15 nm, and the width W ranges from about 10 nm to about 15 nm. In some embodiments, the width W is greater than the height H. As shown in FIG. 7, the highest point of the isolation region 120 in the Z direction is a distance D1 away from a bottom surface of the bottommost second semiconductor layer 108, a distance D2 away from a bottom surface of the middle second semiconductor layer 108, and a distance D3 away from a bottom surface of the topmost second semiconductor layer 108. In some embodiments, the distance D1 ranges from about 3 nm to about 6 nm, the distance D2 ranges from about 33 nm to about 36 nm, and the distance D3 ranges from about 63 nm to about 66 nm. In some embodiments, the distance D1 ranges from about 3 nm to about 6 nm, the distance D2 ranges from about 18 nm to about 21 nm, and the distance D3 ranges from about 33 nm to about 36 nm.

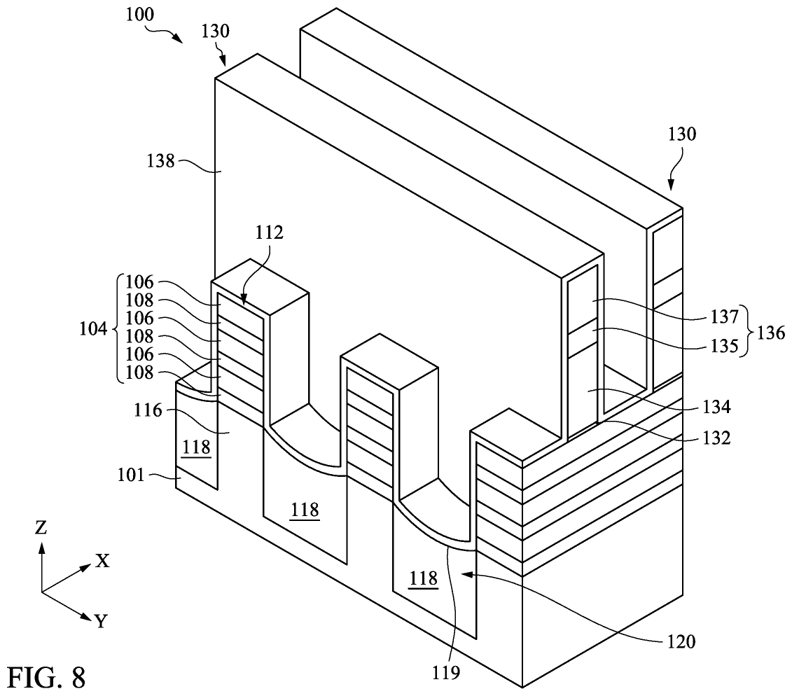

FIGS. 8-12 are perspective views of various stages of manufacturing the semiconductor device structure 100, in accordance with some embodiments. As shown in FIG. 8, a spacer layer 138 is formed to cover the sacrificial gate structures 130, the exposed portions of the fin structures 112, and the exposed portions of the isolation regions 120. The spacer layer 138 may include one or more layers of dielectric material, such as silicon oxide, silicon nitride, silicon carbide, silicon oxynitride, SiCN, silicon oxycarbide, SiOCN, and/or combinations thereof. In some embodiments, the spacer layer 138 is formed by a conformal process, such as an atomic layer deposition (ALD) process. In some embodiments, the spacer layer 138 has a thickness ranging from about 2 nm to about 10 nm.

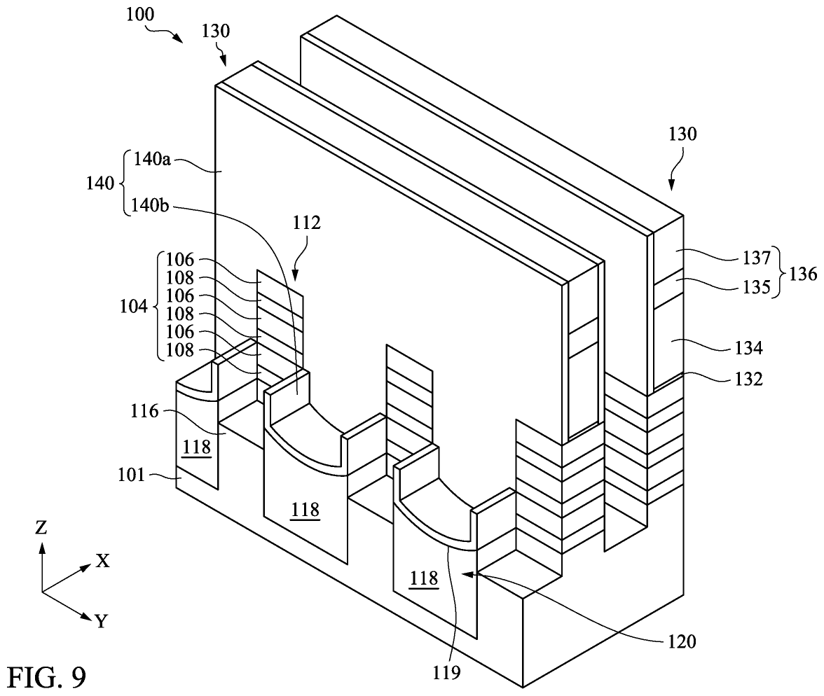

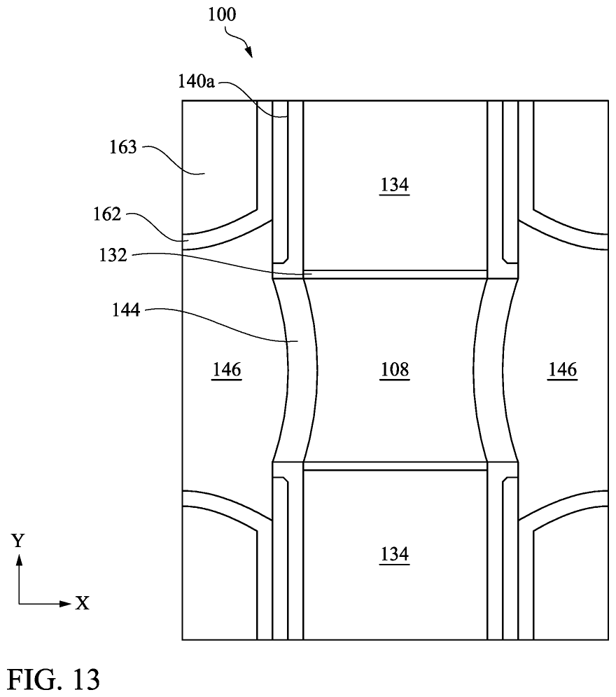

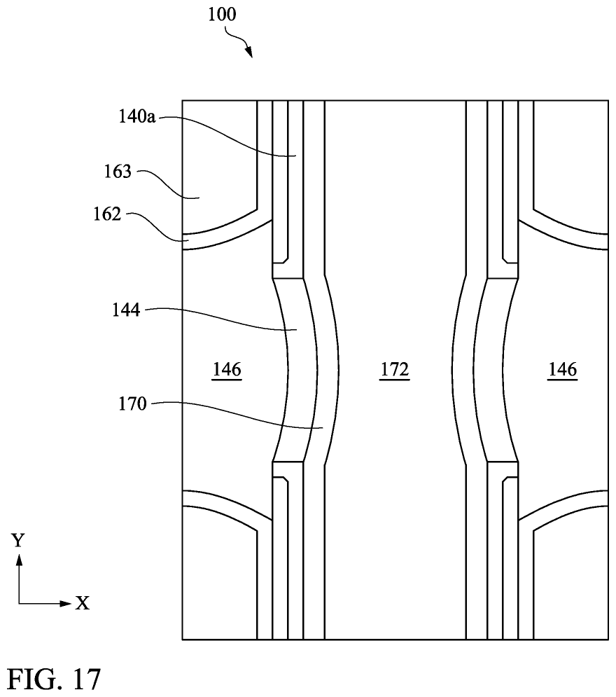

As shown in FIG. 9, one or more etch processes are performed to recess the portions of the fin structures 112 not covered by the sacrificial gate structures 130 and to remove portions of the spacer layer 138. In some embodiments, the portions of the spacer layer 138 formed on tops of the portions of the fin structures 112 not covered by the sacrificial gate structures 130 are removed to expose the portions of the fin structures 112 not covered by the sacrificial gate structures 130. Then, the exposed portions of the fin structures 112 not covered by the sacrificial gate structures 130 are recessed to expose the substrate portions 116, as shown in FIG. 9. In some embodiments, a mask (not shown) may be used to protect portions of the spacer layer 138 formed on the isolation regions 120, as a result, the portions of the spacer layer 138 formed on the isolation regions 120 are not removed. In some embodiments, the mask is not present, and the portions of the spacer layer 138 formed on the isolation regions 120 are also removed. The portions of the spacer layer 138 formed on the mask structure 136 may be also removed. The one or more etch processes may include a dry etch, such as a RIE, NBE, or the like, and/or a wet etch, such as using tetramethyalammonium hydroxide (TMAH), ammonium hydroxide (NH₄OH). The one or more etch processes form spacers 140 including a first portion 140a formed on sidewalls of the sacrificial gate electrode layer 134 and second portions 140b formed on the isolation regions 120 not covered by the sacrificial gate structures 130. As described above, the second portions 140b may not be present in some embodiments. In some embodiments, the spacer 140 includes a single layer, as shown in FIG. 9. In some embodiments, the spacer 140 includes two or more layers, as shown in FIGS. 13 and 17.

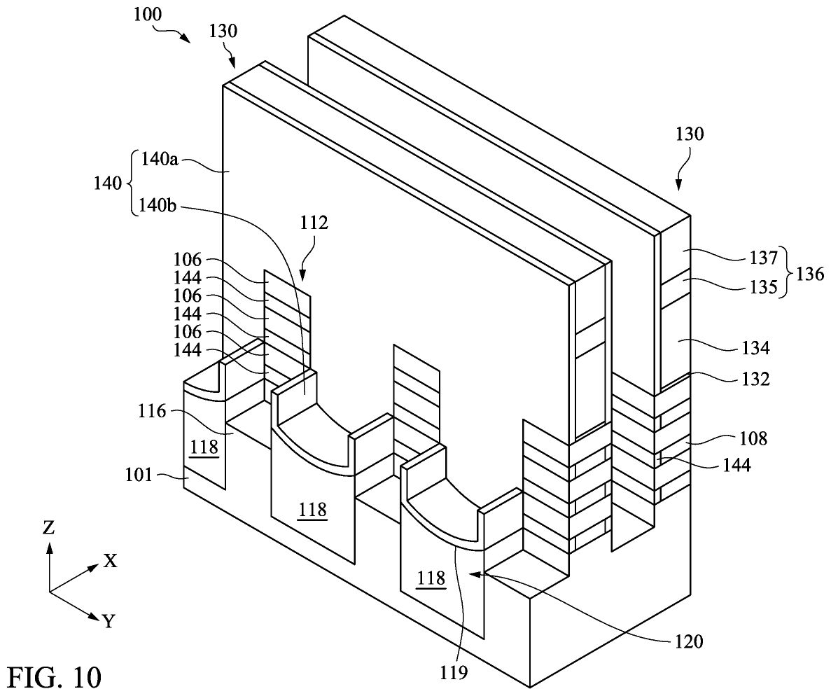

As shown in FIG. 10, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions. After removing edge portions of each second semiconductor layers 108, a dielectric layer is deposited in the cavities to form dielectric spacers 144, as shown in FIG. 10. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

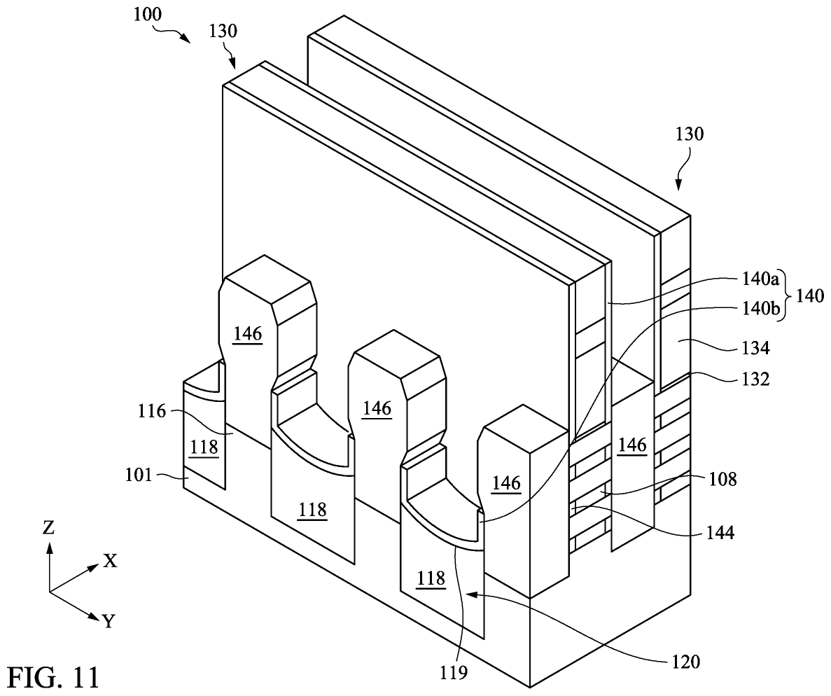

As shown in FIG. 11, source/drain (S/D) regions 146 are formed from the substrate portion 116. The S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

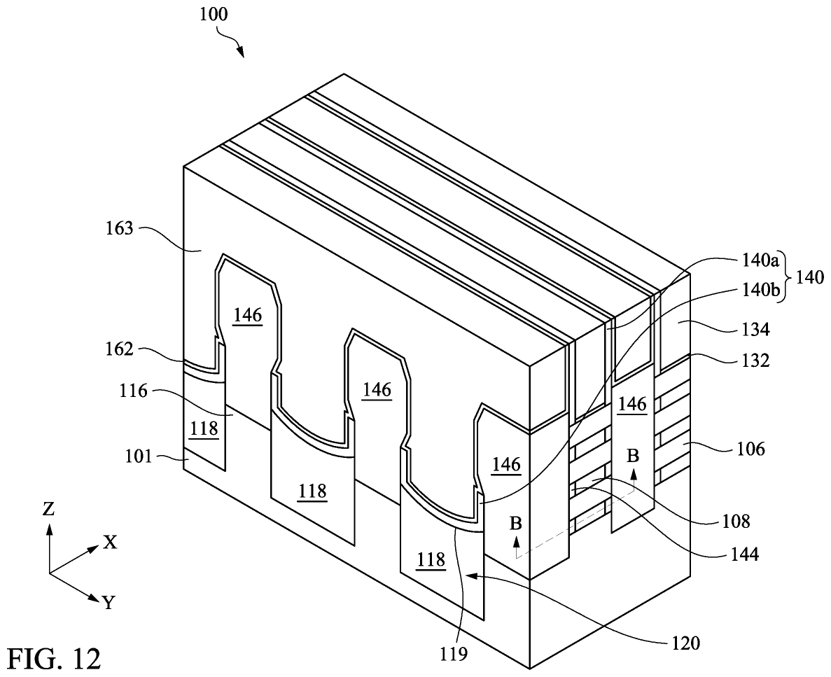

Next, as shown in FIG. 12, a contact etch stop layer (CESL) 162 is conformally formed on the exposed surfaces of the semiconductor device structure 100. The CESL 162 covers the sidewalls of the sacrificial gate structure 130, the second portions 140b of the spacer 140, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162 over the semiconductor device structure 100. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

After the ILD layer 163 is formed, a planarization operation, such as CMP, is performed on the semiconductor device structure 100 until the sacrificial gate electrode layer 134 is exposed, as shown in FIG. 12.

FIG. 13 is a cross-sectional top view of the semiconductor device structure 100 taken along line B-B of FIG. 12, in accordance with some embodiments. As shown in FIG. 13, the S/D regions 146 and the sacrificial gate electrode layer 134 are separated by the first portion 140a of the spacer 140, and the S/D regions 146 and the second semiconductor layers 108 are separated by the dielectric spacers 144. As described above, the slanted top surface 119 of the isolation regions 120 can lead to substantially flat side surfaces of the sacrificial gate electrode layers 134. As a result, no portion of the sacrificial gate electrode layer 134 is extended between the first portion 140a of the spacer 140 and the dielectric spacer 144. In some embodiments, the sacrificial gate electrode layer 134 includes protrusions extending between the first portion 140a of the spacer 140 and the dielectric spacer 144 as a result of substantially flat top surface of the isolation regions 120.

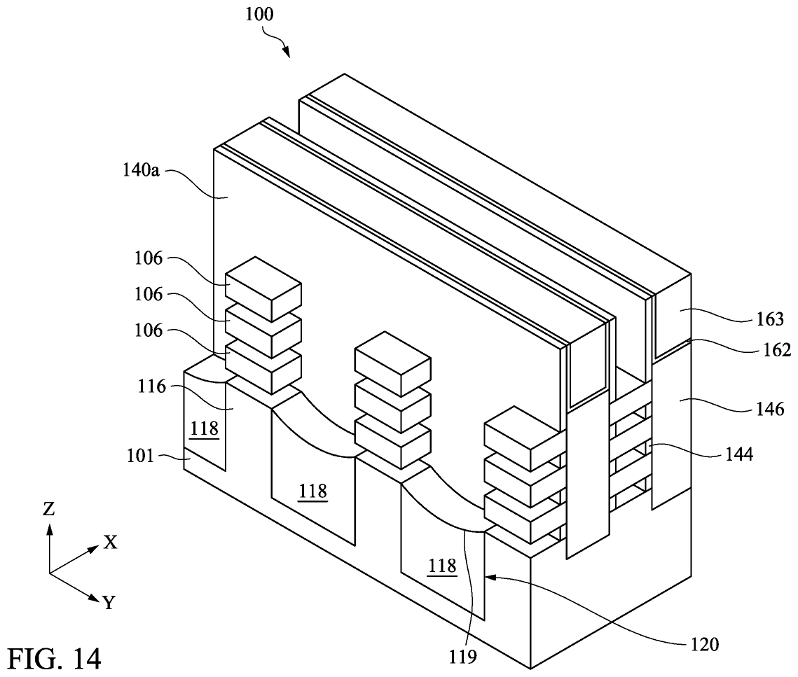

FIGS. 14-16 are perspective views of various stages of manufacturing the semiconductor device structure 100, in accordance with some embodiments. As shown in FIG. 14, the sacrificial gate structures 130 and the second semiconductor layers 108 are removed. The ILD layer 163 protects the S/D regions 146 during the removal processes. The sacrificial gate structure 130 and the second semiconductor layers 108 can be removed using plasma dry etching and/or wet etching. In some embodiments, a wet etchant such as a tetramethylammonium hydroxide (TMAH) solution can be used to selectively remove the sacrificial gate structures 130 and the second semiconductor layers 108 but not the spacers 140, the isolation regions 120, the ILD layer 163, and the CESL 162.

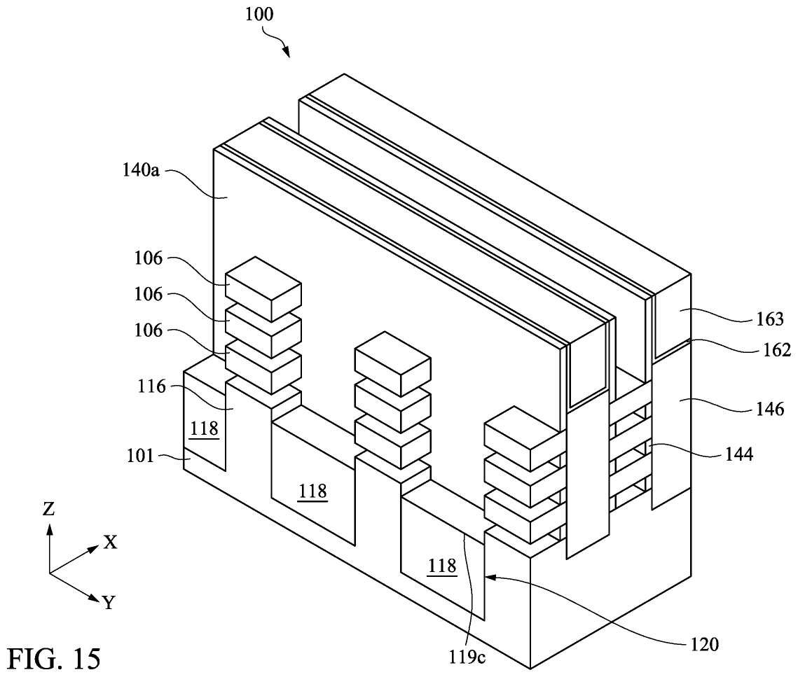

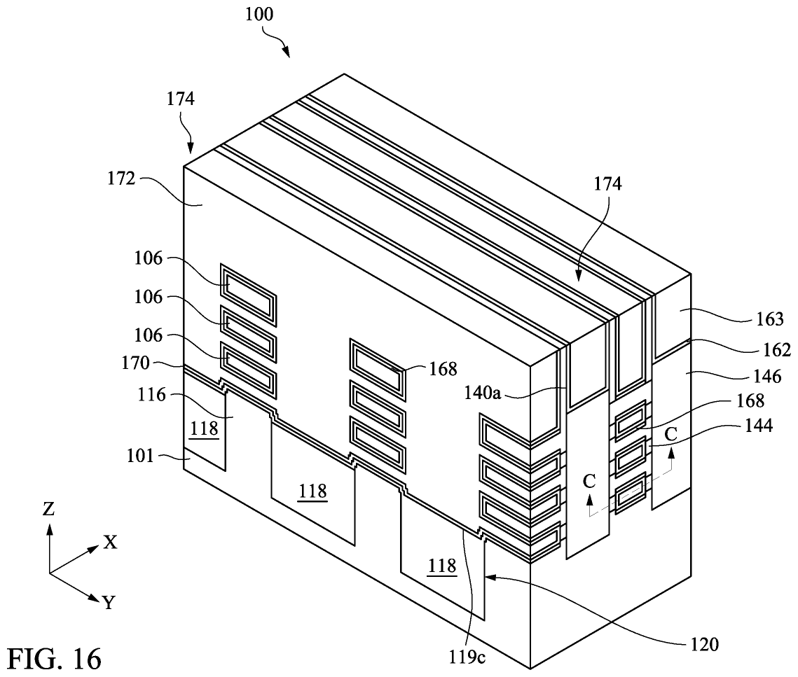

As shown in FIG. 14, in some embodiments, after the removal of the sacrificial gate structures 130 and the second semiconductor layers 108, the slanted top surface 119 of the isolation regions 120 remains. The slanted top surface 119 may lead to increased electrical resistance for the subsequently formed gate electrode layer 172 (FIG. 16). Thus, in some embodiments, an additional etch process is performed after the removal of the sacrificial gate structures 130 and the second semiconductor layers 108 to recess the isolation regions 120. In some embodiments, the additional etch process is a dry etching process. For example, the dry etching process utilizes etchants such as NH₃, NF₃, HBr, H₂, or combinations thereof. In some embodiments, the dry etching process also utilizes passivation gas to enhance selectivity, and the passivation gas includes N₂, O₂, or a combination thereof. With the addition of the passivation gas during the dry etching process, the dry etching process etches the dielectric material of the insulating material 118, while the semiconductor material of the first semiconductor layers 106 is not substantially affected. The gas flow rate of the etchants and passivation gas ranges from about 20 standard cubic centimeters (sccm) to about 3000 sccm. The plasma power of the dry etching process may range from about 10 W to about 4000 W, and the processing pressure may range from about 10 mTorr to about 3 Torr. In some embodiments, a bias voltage is applied during the additional etch process. As a result, the top surface 119c is substantially flat after the additional etch process, as shown in FIG. 15.

Thus, in some embodiments, the isolation region 120 includes a first top surface 119 located between substrate portions 116 (FIG. 12) and a second top surface 119c located in the channel region under the gate electrode layer 172 (FIG. 16). The first top surface 119 has a “smile” or “U” shaped profile, while the second top surface 119c has a substantially flat profile. The “smile” shaped profile of the first top surface 119 helps the sacrificial gate electrode layer 134 to be free of protrusions or residue, while the flat profile of the second top surface 119c helps to reduce electrical resistance of the gate electrode layer 172 (FIG. 16).

As shown in FIG. 16, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) 168 is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 163. The gate dielectric layer 170 and the gate electrode layer 172 formed over the ILD layer 163 are then removed by using, for example, CMP, until the top surface of the ILD layer 163 is exposed.

FIG. 17 is a cross-sectional top view of the semiconductor device structure 100 taken along line C-C of FIG. 16, in accordance with some embodiments. As shown in FIG. 17, the gate dielectric layer 170 and the S/D region 146 are separated by the first portion 140a of the spacer 140 and the dielectric spacer 144. In some embodiments, the thickness of the first portion 140a of the spacer 140 may range from about 5 nm to about 10 nm, and the thickness of the dielectric spacer 144 may be the same as the thickness of the first portion 140a of the spacer 140. With such thick dielectric materials between the gate dielectric layer 170 and the S/D region 146, the risk of electrical short between the gate electrode layer 172 and the S/D region 146 is reduced. In addition, because the first portion 140a of the spacer 140 is in contact with the dielectric spacer 144, the process window for removing the sacrificial gate structure 130 may be enlarged.

Embodiments of the present disclosure provide a semiconductor device structure 100 including an isolation region 120 having a slanted top surface 119 between the substrate portions 116. Some embodiments may achieve advantages. For example, the risk of electrical short between the gate electrode layer 172 and the S/D region 146 is reduced and the process window for removing the sacrificial gate structure 130 is enlarged.

An embodiment is a semiconductor device structure. The structure includes first and second source/drain regions disposed over a substrate and an isolation region disposed between the first and second source/drain regions. The isolation region includes a first top surface having a slanted portion and a flat portion, and a portion of the isolation region located between the slanted portion of the first top surface and a plane defined by the flat portion of the first top surface has a width and a height. The width is greater than the height. The structure further includes a plurality of semiconductor layers disposed adjacent the first and second source/drain regions, a gate electrode layer surrounding a portion of each of the plurality of semiconductor layers, and a spacer disposed between the gate electrode layer and the first source/drain region.

Another embodiment is a semiconductor device structure. The structure includes a first source/drain region disposed over a first substrate portion, a second source/drain region disposed over a second substrate portion, a plurality of semiconductor layers disposed adjacent the first and second source/drain regions, a gate electrode layer surrounding a portion of each of the plurality of semiconductor layers, and an isolation region. The isolation region includes a first top surface located between the first and second substrate portions and a second top surface located under the gate electrode layer. The first top surface has a “U” shaped profile, and the second top surface has a flat profile.

A further embodiment is a method for forming a semiconductor device structure. The method includes forming a fin structure from a substrate, depositing an insulating material around the fin structure over the substrate, and recessing the insulating material to form an isolation region. A first top surface of the isolation region includes a slanted portion and a flat portion, and a portion of the isolation region located between the slanted portion of the first top surface and a plane defined by the flat portion of the first top surface has a width and a height. The width is greater than the height. The method further includes forming a sacrificial gate structure and forming a source/drain region over the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
first and second source/drain regions disposed over a substrate;
an isolation region disposed between the first and second source/drain regions, wherein the isolation region includes a first top surface having a slanted portion and a flat portion, and a portion of the isolation region located between the slanted portion of the first top surface and a plane defined by the flat portion of the first top surface has a width and a height, wherein the width is greater than the height;
a plurality of semiconductor layers disposed adjacent the first and second source/drain regions;
a gate electrode layer surrounding a portion of each of the plurality of semiconductor layers; and
a spacer disposed between the gate electrode layer and the first source/drain region.

2. The semiconductor device structure of claim 1, further comprising a dielectric spacer in contact with the spacer, wherein the dielectric spacer is disposed between the gate electrode layer and the first source/drain region.

3. The semiconductor device structure of claim 1, further comprising a gate dielectric layer disposed between the gate electrode layer and the first source/drain region.

4. The semiconductor device structure of claim 1, wherein the width and the height each ranges from about 10 nm to about 15 nm.

5. The semiconductor device structure of claim 1, wherein the isolation region includes a second top surface located under the gate electrode layer.

6. The semiconductor device structure of claim 5, wherein the second top surface has a profile different from that of the first top surface.

7. The semiconductor device structure of claim 6, wherein the second top surface is flat.

8. A semiconductor device structure, comprising:
a first source/drain region disposed over a first substrate portion;
a second source/drain region disposed over a second substrate portion;
a plurality of semiconductor layers disposed adjacent the first and second source/drain regions;
a gate electrode layer surrounding a portion of each of the plurality of semiconductor layers; and
an isolation region, wherein the isolation region includes a first top surface located between the first and second substrate portions and a second top surface located under the gate electrode layer, the first top surface has a “U” shaped profile, and the second top surface has a flat profile.

9. The semiconductor device structure of claim 8, wherein the first top surface forms an angle with respect to a side surface of the first substrate portion.

10. The semiconductor device structure of claim 9, wherein the angle ranges from about 105 degrees to about 130 degrees.

11. The semiconductor device structure of claim 8, further comprising a spacer disposed between the gate electrode layer and the first source/drain region.

12. The semiconductor device structure of claim 11, further comprising a dielectric spacer in contact with the spacer, wherein the dielectric spacer is disposed between the gate electrode layer and the first source/drain region.

13. The semiconductor device structure of claim 12, further comprising a gate dielectric layer disposed between the gate electrode layer and the first source/drain region.

14. A method for forming a semiconductor device structure, comprising:
forming a fin structure from a substrate;
depositing an insulating material around the fin structure over the substrate;
recessing the insulating material to form an isolation region, wherein a first top surface of the isolation region includes a slanted portion and a flat portion, and a portion of the isolation region located between the slanted portion of the first top surface and a plane defined by the flat portion of the first top surface has a width and a height, wherein the width is greater than the height;
forming a sacrificial gate structure; and
forming a source/drain region over the substrate.

15. The method of claim 14, wherein the insulating material is recessed by a first dry etching process.

16. The method of claim 15, wherein the first dry etching process is without a bias voltage.

17. The method of claim 16, further comprising removing the sacrificial gate structure to expose the first top surface of the isolation region.

18. The method of claim 17, further comprising removing portions of the first top surface to form a second top surface of the isolation region.

19. The method of claim 18, wherein the second top surface of the isolation region has a flat profile.

20. The method of claim 17, wherein a second dry etching process is performed to remove the portions of the first top surface, wherein the second dry etching process includes a bias voltage.
